(19) United States
(12) Patent Application Publication
(10) Pub. No.: US 2022/0386508 A1
(43) Pub. Date: Dec. 1, 2022

(54) ELECTRONIC COMPONENT

(71) Applicant: SHARP KABUSHIKI KAISHA, Sakai City (JP)

(72) Inventors: HIDENORI KUWAJIMA, Sakai City (JP); HIROKI TANABE, Sakai City (JP)

(21) Appl. No.: 17/719,000

(22) Filed: Apr. 12, 2022

(30) Foreign Application Priority Data
May 26, 2021 (JP) 2021-088260

(51) Int. Cl. H05K 7/20

(52) U.S. Cl. CPC H05K 7/20445

(57) ABSTRACT

An electronic component comprises a heat source component provided on a substrate; a case component covering the heat source component; a heat receiving component facing the case component; and a wall portion protruding from the heat receiving component, the wall portion configured to transfer heat indirectly transferred from the heat source component to the heat receiving component, wherein a heat release path of heat indirectly transferred from the heat source component to the wall portion includes a path away from the heat receiving component, the path extending in a wall portion direction toward the wall portion in a direction along a front surface of the heat receiving component.

### CROSS-REFERENCE TO RELATED APPLICATION

The present application claims priority from Japanese Application JP2021-088260, the content to which is hereby incorporated by reference into this application.

### BACKGROUND OF THE INVENTION

### 1. Field of the Invention

The present disclosure relates to an electronic component.

### 2. Description of the Related Art

JP 2011-211424 A discloses a millimeter wave transceiver including a millimeter wave communication IC, which is a heat source that generates heat, and a heat sink that releases heat of the millimeter wave communication IC, in a housing. In the housing, the heat sink is in direct contact with the millimeter wave communication IC to release heat of the millimeter wave communication IC.

### SUMMARY OF THE INVENTION

According to the millimeter wave transceiver of JP 2011-211424 A, the millimeter wave communication IC is covered by the housing capable of accommodating both the millimeter wave communication IC and the heat sink. Thus, according to the millimeter wave transceiver of JP 2011-211424 A, it is possible to bring the heat sink in direct contact with the millimeter wave communication IC to release heat of the millimeter wave communication IC in the housing.

However, there is a case where a heat source component such as the millimeter wave communication IC is covered by a case component other than the housing, for example, a shield case, and it is impossible to bring the heat source component in direct contact with the heat sink. In such a configuration in which a heat source component is covered by a case component other than a housing, a technique of releasing heat from the heat source component efficiently is desired. The present disclosure is directed to providing an electronic component capable of efficiently releasing heat from a heat source component that is covered by a case component and cannot release heat directly.

An electronic component of the present disclosure includes: a heat source component provided on a substrate; a case component covering the heat source component; a heat receiving component facing the case component; and a wall portion protruding from the heat receiving component, the wall portion configured to transfer heat indirectly transferred from the heat source component to the heat receiving component, wherein a heat release path of heat indirectly transferred from the heat source component to the wall portion includes a path away from the heat receiving component, the path extending in a wall portion direction toward the wall portion in a direction along a front surface of the heat receiving component.

### BRIEF DESCRIPTION OF THE DRAWINGS

FIG. 1 is a cross-sectional view of an electronic component according to an embodiment.

FIG. 2 is a perspective view illustrating a configuration of a wall portion and a heat receiving component in the electronic component according to the embodiment.

FIG. 3 is a cross-sectional view of an electronic component according to a first modified example of the embodiment.

FIG. 4 is a cross-sectional view of an electronic component according to a second modified example of the embodiment.

FIG. 5 is a cross-sectional view of an electronic component according to a third modified example of the embodiment.

### DETAILED DESCRIPTION OF THE INVENTION

An electronic component of the present disclosure will be described below with reference to the drawings. In the drawings, identical or equivalent elements are given the same reference signs, and redundant descriptions of the identical or equivalent elements are not repeated.

### Embodiment

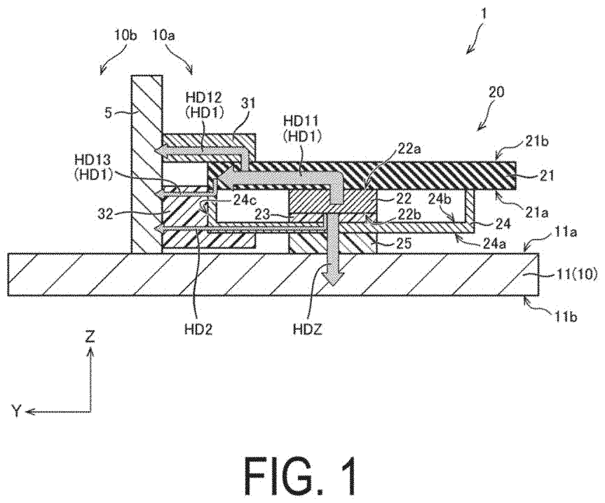

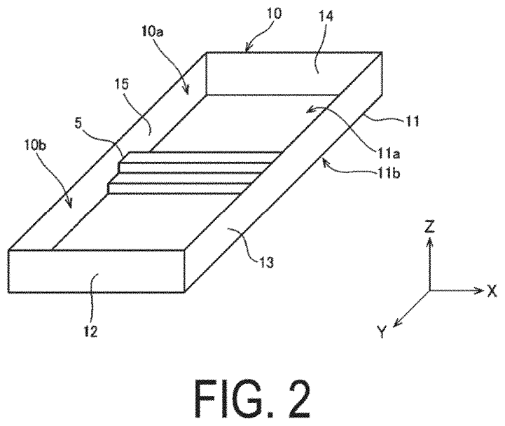

A configuration of an electronic component 1 according to an embodiment will be described with reference to FIGS. 1 and 2. FIG. 1 is a cross-sectional view of the electronic component 1 according to the embodiment. FIG. 2 is a perspective view illustrating a configuration of a wall portion 5 and a container component 10 in the electronic component 1 according to the embodiment.

The electronic component 1 includes the wall portion 5, the container component 10, a heat source assembly 20, and a first heat transfer component 31, and a second heat transfer component 32. The heat source assembly 20 includes a substrate 21, a heat source component 22, heat transfer components 23, 25, and a case component 24. The heat source assembly 20 has a configuration in which the heat source component 22 mounted on the substrate 21 is covered by the case component 24.

The container component 10 is a member referred to as a so-called sheet metal. The container component 10 is a component serving as a container for accommodating the heat source assembly 20. The container component 10 includes a heat receiving component 11 that is a bottom plate portion and side portions 12 to 15, and has a box shape an upper surface of which is open, for example. The container component 10 is provided with the heat source assembly 20 in a space inside the container component 10 to serve as a base of the heat source assembly 20. The container component 10 may be used as a housing of an electronic device when the electronic component 1 is used in the electronic device, or may be used as a reinforcing component that is provided inside a housing of an electronic device to reinforce the housing. Note that examples of the electronic device in which the electronic component 1 is provided include a mobile terminal such as a smartphone, an information terminal such as a personal computer, and other electronic devices.

Furthermore, the container component 10 has a heat release function higher than that of the heat source assembly 20, so that as described below, heat generated by the heat source assembly 20 is transferred to the heat receiving component 11, and the transferred heat is efficiently released throughout the container component 10 including the heat receiving component 11. In other words, the container component 10 including the heat receiving component 11 can be expressed as a heat sink that releases heat from the heat source component 22 of the heat source assembly 20.

For example, the container component 10 can be formed of a metal material having a high heat release function. Examples of the metal material having a high heat release function include stainless steel or aluminum.

The heat receiving component 11 is a member having a plate shape. The side portions 12 to 15 are erected at ends of the heat receiving component 11. Note that the heat receiving component 11 and the side portions 12 to 15 may be integrally formed. The side portion 12 and the side portion 14 are erected with respect to the heat receiving component 11 so as to face each other with the heat receiving component 11 interposed therebetween. The side portion 13 and the side portion 15 are erected with respect to the heat receiving component 11 so as to face each other with the heat receiving component 11 interposed therebetween. Note that, of both main surfaces of the heat receiving component 11, a surface located in a space inside the container component 10 (a space surrounded by the heat receiving component 11, and the side portions 12 to 15) is referred to as a front surface 11a, and a surface on a side opposite to the front surface 11a is referred to as a rear surface 11b.

For example, a shape of the heat receiving component 11 in a plan view is a rectangular shape. As an example, in the heat receiving component 11 in a plan view, sides where the side portions 13, 15 are provided are long sides, and sides where the side portions 12, 14 are provided are short sides. Note that the shape of the heat receiving component 11 in a plan view is not limited to a rectangular shape, and may be a square shape or any shapes other than a quadrangular shape.

The wall portion 5 is provided so as to protrude from the front surface 11a of the heat receiving component 11 in a direction away from the front surface 11a. For example, the wall portion 5 is a partition plate provided in the space inside the container component 10 to divide the space inside the container component 10 into a plurality of spaces 10a, 10b. In addition, the wall portion 5 has a function of transferring heat indirectly transferred from the heat source component 22 to the heat receiving component 11, as described below. For example, the wall portion 5 can be formed of a metal material having a high heat release function. Examples of the metal material having a high heat release function include stainless steel or aluminum. The wall portion 5 may be formed integrally with the container component 10, or may be provided by inserting a component different from the container component 10 into the container component 10.

Here, a direction along the front surface 11a of the heat receiving component 11, the direction being from the side portion 14 toward the wall portion 5, is referred to as a wall portion direction. The wall portion direction is assumed to be a Y-axis direction. In addition, a direction along the front surface 11a of the heat receiving component 11, the direction being from the side portion 15 toward the side portion 13, that is, a direction orthogonal to the wall portion direction (Y-axis direction), is assumed to be an X-axis direction. The front surface 11a of the heat receiving component 11 is an XY-axis plane. The normal direction of the heat receiving component 11 with respect to the front surface 11a is assumed to be a Z-axis direction. Note that the Z-axis direction is a direction in which the wall portion 5 protrudes from the front surface 11a.

The heat source assembly 20 is provided in a space 10a of the space inside the container component 10. The heat source assembly 20 is provided in contact with the front surface 11a of the heat receiving component 11, and is provided separately from the wall portion 5.

The substrate 21 is a flat plate made of resin. A circuit and a wiring line are mounted on each of a first surface 21a and a second surface 21b, which are both main surfaces of the substrate 21. The first surface 21a is a surface facing the front surface 11a of the heat receiving component 11 with the case component 24 interposed therebetween, and the second surface 21b is a surface on a side opposite to the first surface 21a.

The heat source component 22 is, for example, a CPU or a memory, and is an electrical element that operates to generate heat. As a specific example of the heat source component 22, a system-on-a-chip (SoC) can be exemplified. The heat source component 22 is provided in a space between the substrate 21 and the case component 24, for example. The heat source component 22 is provided on the substrate 21. For example, the heat source component 22 includes a first surface 22a provided with a plurality of terminals mounted on the substrate 21, and a second surface 22b on a side opposite to the first surface 22a. The first surface 22a of the heat source component 22 is mounted on the first surface 21a of the substrate 21 to be electrically connected to the wiring line provided on the first surface 21a of the substrate 21. The second surface 22b of the heat source component 22 faces the case component 24.

The case component 24 is provided on the substrate 21 so as to cover the heat source component 22. For example, the case component 24 is a shield case that protects the heat source component 22 from an electromagnetic noise from the outside of the electronic component 1. The case component 24 can be formed using a metal material, for example. When the case component 24 is a shield case, the case component 24 can be formed using, for example, nickel silver, silver, copper, aluminum, or the like.

The case component 24 is provided so as to face the front surface 11a of the heat receiving component 11. In the case component 24, a surface facing the front surface 11a of the heat receiving component 11 is referred to as a first surface 24a, and a surface on a side opposite to the first surface 24a, which faces the first surface 21a of the substrate 21, is referred to as a second surface 24b.

The case component 24 may completely cover the heat source component 22, but does not need to completely cover the heat source component 22, for example, by providing an opening. In other words, a space formed by the substrate 21 and the case component 24, in which the heat source component 22 is provided, may be sealed, or may be a space not sealed, for example, by providing an opening in the case component 24.

The heat transfer components 23, 25 each are a component for transferring heat from the heat source component 22 to the front surface 11a of the heat receiving component 11.

The heat transfer component 23 is in contact with the second surface 22b of the heat source component 22 and the second surface 24b of the case component 24. The heat transfer component 25 is in contact with the first surface 24a of the case component 24 and the front surface 11a of the heat receiving component 11. The heat transfer components 23, 25 can be formed using a thermally conductive material called a thermal interface material (TIM), for example. For example, the heat transfer components 23, 25 can be flexible, sheet-like, grease-like, or gel-like.

In this way, the heat transfer component 23 connects the heat source component 22 and the case component 24, and the heat transfer component 25 connects the case component 24 and the heat receiving component 11. This allows the heat source component 22 to be connected to the front surface 11a of the heat receiving component 11 facing the heat source component 22 via the heat transfer component 23, the case component 24, and the heat transfer component 25. In other words, the heat source component 22 is indirectly connected to the front surface 11a of the heat receiving component 11.

This forms a heat release path HDZ in which heat generated by the heat source component 22 is transferred to the front surface 11a of the heat receiving component 11 through the heat source component 22, the heat transfer component 23, the case component 24, and the heat transfer component 25. The heat release path HDZ is a path in which heat is transferred from the heat source component 22 to the front surface 11a of the heat receiving component 11 in a direction intersecting the front surface 11a (e.g., a vertical direction).

This allows heat generated by the heat source component 22 to be transferred to the heat receiving component 11 through the heat release path HDZ even when the heat source component 22 is covered by the case component 24 and cannot be in direct contact with the heat receiving component 11. As a result, heat generated by the heat source component 22 can be released by the heat receiving component 11.

Furthermore, the electronic component 1 according to the present embodiment has a configuration in which in order to more efficiently release heat generated by the heat source component 22, a path in the wall portion direction, which is a heat release path in which heat is indirectly transferred from the heat source component 22 to the wall portion 5 in a direction along the front surface 11a of the heat receiving component 11 (Y-axis direction), is formed as a heat release path of heat generated by the heat source component 22, in addition to the heat release path HDZ toward the front surface 11a in the direction intersecting the front surface 11a of the heat receiving component 11 (e.g., the vertical direction). Note that the path in the wall portion direction is a path away from the heat receiving component 11 (in other words, a path different from the path extending in the direction along the front surface 11a of the heat receiving component 11 (Y-axis direction) in the heat receiving component 11).

Specifically, for example, in the electronic component 1, a first heat release path HD1 and a second heat release path HD2 are formed as a path in the wall portion direction, which is a heat release path in which heat is indirectly transferred from the heat source component 22 to the wall portion 5, in a direction along the front surface 11a of the heat receiving component 11 (Y-axis direction).

The first heat release path HD1 is a path in which heat generated by the heat source component 22 is transferred from the heat source component 22 to the substrate 21, directed to the wall portion 5 over the substrate 21 in the direction along the front surface 11a of the heat receiving component 11 (Y-axis direction), and indirectly transferred to the wall portion 5 from the substrate 21 in the direction along the front surface 11a of the heat receiving component 11 (Y-axis direction). In the first heat release path HD1, heat generated by the heat source component 22 is mainly transferred from the first surface 22a of the heat source component 22 to the substrate 21.

The second heat release path HD2 is a path in which heat generated by the heat source component 22 is transferred from the heat source component 22 to the case component 24, directed to the wall portion 5 over the case component 24 in the direction along the front surface 11a of the heat receiving component 11 (Y-axis direction), and indirectly transferred to the wall portion 5 from the case component 24 in the direction along the front surface 11a of the heat receiving component 11 (Y-axis direction). In the second heat release path HD2, heat generated by the heat source component 22 is mainly transferred from the second surface 22b of the heat source component 22 to the case component 24 over the heat transfer component 23.

The electronic component 1 includes, for example, the first heat transfer component 31 and the second heat transfer component 32 in order to form the first heat release path HD1 and the second heat release path HD2. The first heat transfer component 31 and the second heat transfer component 32 are provided so as to connect the heat source assembly 20 and the wall portion 5 by transferring heat from the heat source assembly 20 to the wall portion 5. For example, each of the first heat transfer component 31 and the second heat transfer component 32 is provided extending along the front surface 11a of the heat receiving component 11.

The first heat transfer component 31 and the second heat transfer component 32 can be formed using a thermally conductive material called a TIM, for example. For example, the first heat transfer component 31 and the second heat transfer component 32 can be flexible, sheet-like, grease-like, or gel-like.

The first heat transfer component 31 constitutes the first heat release path HD1. The first heat transfer component 31 connects the substrate 21 on which the heat source component 22 is mounted and the wall portion 5. For example, the first heat transfer component 31 is in contact with the second surface 21b of the substrate 21, extends in a direction toward the wall portion 5, and is also in contact with the wall portion 5. The second heat transfer component 32 constitutes the first heat release path HD1 and the second heat release path HD2. The second heat transfer component 32 connects the case component 24 that covers the heat source component 22 and the wall portion 5. For example, the second heat transfer component 32 is in contact with the case component 24 over a side surface 24c facing the wall portion 5 and the first surface 24a of the case component 24, extends in the direction toward the wall portion 5, and is also in contact with the wall portion 5. The second heat transfer component 32 is provided away from the heat receiving component 11. Note that the second heat transfer component 32 may be in contact with the heat receiving component 11.

In this way, the first heat transfer component 31 and the second heat transfer component 32 are provided to form the first heat release path HD1. Specifically, for example, the first heat release path HD1 includes two path combinations, that is, a path HD11 passing through the substrate 21 and a path HD12 passing through the first heat transfer component 31, and the path HD11 passing through the substrate 21 and a path HD13 passing through the second heat transfer component 32.

The path HD11 passing through the substrate 21 is a path in which heat generated by the heat source component 22 and transferred from the heat source component 22 to the substrate 21 is directed to the wall portion 5 over the substrate 21 in the direction along the front surface 11a of the heat receiving component 11 (Y-axis direction). The path HD12 passing through the first heat transfer component 31 and the path HD13 passing through the second heat transfer component 32 each are a path that branches from the path HD11 passing through the substrate 21 in the wall portion direction. Specifically, the path HD12 passing through the first heat transfer component 31 is a path in which part of heat transferred over the substrate 21 is transferred to the first heat transfer component 31, transferred over the first heat transfer component 31 in the direction along the front surface 11a of the heat receiving component 11 (Y-axis direction), and reaches the wall portion 5. The path HD13 passing through the second heat transfer component 32 is a path in which part of heat transferred over the substrate 21 is transferred to the second heat transfer component 32, transferred over the second heat transfer component 32 in the direction along the front surface 11a of the heat receiving component 11 (Y-axis direction), and reaches the wall portion 5. The heat transferred to the wall portion 5 is transferred to the heat receiving component 11 over the wall portion 5.

The first heat transfer component 31 is provided in this way, so that the heat source component 22 and the wall portion 5 can be indirectly connected via the substrate 21 and the first heat transfer component 31. This can form the path HD11 and the path HD12 of the first heat release path HD1. In addition, the second heat transfer component 32 is provided, so that the heat source component 22 and the wall portion 5 can be indirectly connected via the substrate 21 and the second heat transfer component 32. This can form the path HD11 and the path HD13 of the first heat release path HD1.

On the other hand, the second heat transfer component 32 is provided to form the second heat release path HD2. Specifically, the second heat release path HD2 is a path in which heat generated by the heat source component 22 is transferred from the heat source component 22 to the case component 24, directed to the wall portion 5 over the case component 24 in the direction along the front surface 11a of the heat receiving component 11 (Y-axis direction), further transferred from the case component 24 to the second heat transfer component 32, transferred over the second heat transfer component 32 in the direction along the front surface 11a of the heat receiving component 11 (Y-axis direction), and transferred from the second heat transfer component 32 to the wall portion 5. The heat transferred to the wall portion 5 is transferred to the heat receiving component 11 over the wall portion 5.

The second heat transfer component 32 is provided in this way, so that the heat source component 22 and the wall portion 5 can be indirectly connected via the heat transfer component 23, the case component 24, and the second heat transfer component 32. This can form the second heat release path HD2.

As described above, the electronic component 1 includes the heat source component 22 provided on the substrate 21, the case component 24 that covers the heat source component 22, the heat receiving component 11 provided to face the case component 24, and the wall portion 5 provided to protrude from the heat receiving component 11. The wall portion 5 transfers heat indirectly transferred from the heat source component 22 to the heat receiving component 11. Furthermore, the heat release path of heat transferred indirectly from the heat source component 22 to the wall portion 5 includes the first heat release path HD1 and the second heat release path HD2 that are paths away from the heat receiving component 11, the paths extending in the wall portion direction toward the wall portion 5 in the direction along the front surface 11a of the heat receiving component 11 (Y-axis direction).

This releases heat, which cannot be directly released because the heat source component 22 is covered by the case component 24 and the substrate 21, indirectly from the heat source component 22 in the wall portion direction (Y-axis direction), so that as compared to a case where there is no heat release path in the wall portion direction (Y-axis direction), for example, a case where only the heat release path HDZ in the direction intersecting the front surface 11a of the heat receiving component 11 is present, it is possible to efficiently release heat from the heat source component 22 covered by the case component 24 and the substrate 21.

Specifically, the electronic component 1 includes the first heat release path HD1 extending through the substrate 21 to the wall portion 5 as a path in the wall portion direction, which is a heat release path of heat transferred indirectly from the heat source component 22 to the wall portion 5. The substrate 21 is in contact with the heat source component 22 that is a source of heat, so that heat generated by the heat source component 22 is likely to be transferred to the substrate 21. Thus, by providing the first heat release path HD1 that transfers heat from the heat source component 22, which has been transferred to the substrate 21, to the wall portion 5, it is possible to more efficiently transfer heat from the heat source component 22 to the wall portion 5 and transfer the heat from the wall portion 5 to the heat receiving component 11.

The electronic component 1 also includes the first heat transfer component 31 that connects the substrate 21 and the wall portion 5. In the electronic component 1, a path from the substrate 21 to the wall portion 5 through the first heat transfer component 31, which is the first heat release path HD1, is formed. The first heat transfer component 31 is provided in this way, so that the heat source component 22 and the wall portion 5 can be indirectly connected via the substrate 21 and the first heat transfer component 31. This can form the first heat release path HD1 from the heat source component 22 to the wall portion 5 through the substrate 21 and the first heat transfer component 31. Specifically, the path HD11 and the path HD12 can be formed. As a result, it is possible to efficiently transfer heat from the heat source component 22 to the wall portion 5 and transfer the heat from the wall portion 5 to the heat receiving component 11.

In addition, the electronic component 1 includes the second heat release path HD2 extending through the case component 24 to the wall portion 5 as a path in the wall portion direction, which is a heat release path of heat transferred indirectly from the heat source component 22 to the wall portion 5.

Here, the case component 24 covers the heat source component 22, which is a source of heat, and thus heat generated by the heat source component 22 is more likely to be transferred to the case component 24. In addition, for example, the case component 24 is connected to the heat source component 22 via the heat transfer component 23, and also in view of this, heat generated by the heat source component 22 is more likely to be transferred to the case component 24. Thus, by providing the second heat release path HD2 that transfers heat from the heat source component 22, which has been transferred to the case component 24, to the wall portion 5, it is possible to more efficiently transfer heat from the heat source component 22 to the wall portion 5 and transfer the heat from the wall portion 5 to the heat receiving component 11.

Furthermore, for example, even in a case where the first heat transfer component 31 does not have an enough contact area between the first heat transfer component 31 and the second surface 21b of the substrate 21 due to an effect of the wiring line or the like provided on the second surface 21b of the substrate 21, by providing the second heat release path HD2 different from the first heat release path HD1, it is possible to more efficiently transfer heat from the heat source component 22 to the wall portion 5 and transfer the heat from the wall portion 5 to the heat receiving component 11.

In addition, the electronic component 1 has the second heat transfer component 32 that connects the case component 24 and the wall portion 5. In the electronic component 1, a path from the case component 24 to the wall portion 5 through the second heat transfer component 32, which is the second heat release path HD2, is formed.

The second heat transfer component 32 is provided in this way, so that the heat source component 22 and the wall portion 5 can be indirectly connected via the heat transfer component 23, the case component 24, and the second heat transfer component 32. This can form the second heat release path HD2 from the heat source component 22 to the wall portion 5 through the heat transfer component 23, the case component 24, and the second heat transfer component 32. As a result, it is possible to efficiently transfer heat from the heat source component 22 to the wall portion 5 and transfer the heat from the wall portion 5 to the heat receiving component 11.

In addition, the second heat transfer component 32 is provided, so that the heat source component 22 and the wall portion 5 can also be indirectly connected via the substrate 21, the case component 24, and the second heat transfer component 32. This can also form the first heat release path HD1 from the heat source component 22 to the wall portion 5 through the substrate 21, the case component 24, and the second heat transfer component 32. Specifically, the path HD11 and the path HD13 can be formed. As a result, it is possible to further efficiently transfer heat from the heat source component 22 to the wall portion 5 and transfer the heat from the wall portion 5 to the heat receiving component 11.

For example, the second heat transfer component 32 is in contact with the wall portion 5 and the side surface 24c of the case component 24 facing the wall portion 5. This makes it possible not only to transfer heat from the first surface 24a with which the heat transfer component 25 is in contact to the heat receiving component 11 through the heat transfer component 25, but also to transfer heat from the side surface 24c with which the second heat transfer component 32 is in contact to the wall portion 5 through the second heat transfer component 32, in the case component 24. As described above, heat is transferred from the case component 24 in a plurality of directions, so that it is possible to more efficiently release heat generated by the heat source component 22.

Note that the electronic component 1 may have a configuration in which the heat release path HDZ is not formed, for example, by eliminating the heat transfer component 25, because the path in the wall portion direction toward the wall portion 5 in the direction along the front surface 11a of the heat receiving component 11 (Y-axis direction), which is a heat release path of heat indirectly transferred from the heat source component 22 to the wall portion 5, is formed, as described above.

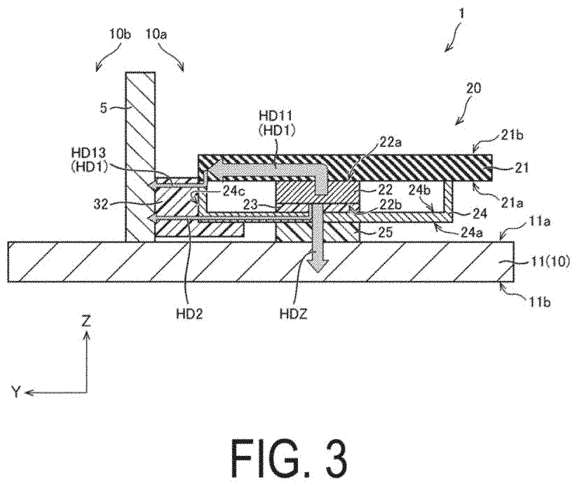

Furthermore, the path in the wall portion direction toward the wall portion 5 in the direction along the front surface 11a of the heat receiving component 11 (Y-axis direction), which is the heat release path of heat indirectly transferred from the heat source component 22 to the wall portion 5, is not limited to the first heat release path HD1 and the second heat release path HD2 illustrated in FIG. 1, and may have other various aspects. Next, with reference to FIGS. 3 to 5, several modified examples will be described.

FIG. 3 is a cross-sectional view of an electronic component 1 according to a first modified example of the embodiment. From the electronic component 1 illustrated in FIG. 1, at least one of the first heat transfer component 31 and the second heat transfer component 32 may be eliminated. The electronic component 1 according to the first modified example illustrated in FIG. 3 has a configuration in which the first heat transfer component 31 is eliminated from the electronic component 1 illustrated in FIG. 1.

As illustrated in FIG. 3, the electronic component 1 includes the second heat transfer component 32 that connects the case component 24 and the wall portion 5. This forms a path from the case component 24 to the wall portion 5 through the second heat transfer component 32, which is the second heat release path HD2, in the electronic component 1. As a result, it is possible to efficiently transfer heat from the heat source component 22 to the wall portion 5 and transfer the heat from the wall portion 5 to the heat receiving component 11, as compared to a case where there is no second heat release path HD2. In addition, by providing the second heat transfer component 32, it is also possible to form the first heat release path HD1 (the path HD11 and the path HD13) from the heat source component 22 to the wall portion 5 through the substrate 21, the case component 24, and the second heat transfer component 32. As a result, it is possible to efficiently transfer heat from the heat source component 22 to the wall portion 5 and transfer the heat from the wall portion 5 to the heat receiving component 11, as compared to a case where there is no first heat release path HD1 (the path HD11 and the path HD13).

Furthermore, the second heat transfer component 32 does not need to be in contact with the first surface 24a of the case component 24, and only need be in contact with at least the side surface 24c of the case component 24 facing the wall portion 5. With this configuration as well, the second heat transfer component 32 is in contact with the wall portion 5 and the side surface 24c of the case component 24 facing the wall portion 5. This can transfer heat from the side surface 24c with which the second heat transfer component 32 is in contact to the wall portion 5 via the second heat transfer component 32, so that it is possible to efficiently release heat generated by the heat source component 22.

Note that although not illustrated, the electronic component 1 may have a configuration in which the second heat transfer component 32 of the first heat transfer component 31 and the second heat transfer component 32 is eliminated from the electronic component 1 illustrated in FIG. 1.

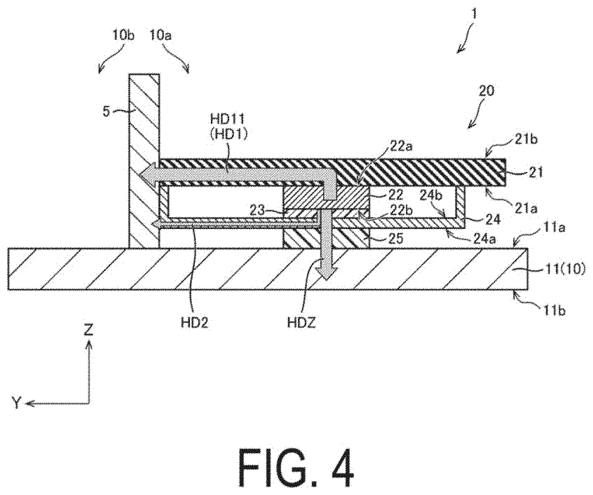

FIG. 4 is a cross-sectional view of an electronic component 1 according to a second modified example of the embodiment. As illustrated in FIG. 4, the electronic component 1 does not need to have the first heat transfer component 31 and the second heat transfer component 32 illustrated in FIG. 1, and the heat source assembly 20 may be brought into contact with the wall portion 5.

Thus, in the electronic component 1 according to the second modified example, the case component 24 and the wall portion 5 are in contact with each other. As a result, as a heat release path of heat indirectly transferred from the heat source component 22 to the wall portion 5, a path away from the heat receiving component 11, which is a path extending in the wall portion direction toward the wall portion 5 in the direction along the front surface 11a of the heat receiving component 11, is formed. This can efficiently release heat generated by the heat source component 22, as compared to a case where the path extending in the wall portion direction is not formed.

Specifically, in the electronic component 1 according to the second modified example, the second heat release path HD2 extending directly to the wall portion 5 through the case component 24 is formed as the path extending in the wall portion direction that is the heat release path of heat indirectly transferred from the heat source component 22 to the wall portion 5. This can efficiently transfer heat from the heat source component 22 to the wall portion 5 and transfer the heat from the wall portion 5 to the heat receiving component 11, as compared to a case where the second heat release path HD2 is not formed.

In addition, in the electronic component 1 according to the second modified example, the substrate 21 is in contact with the wall portion 5. As a result, as the path extending in the wall portion direction, which is the heat release path of heat indirectly transferred from the heat source component 22 to the wall portion 5, the first heat release path HD1 (path HD11) extending directly to the wall portion 5 through the substrate 21 is formed. This can efficiently transfer heat from the heat source component 22 to the wall portion 5 and transfer the heat from the wall portion 5 to the heat receiving component 11, as compared to a case where the first heat release path HD1 (path HD11) is not formed.

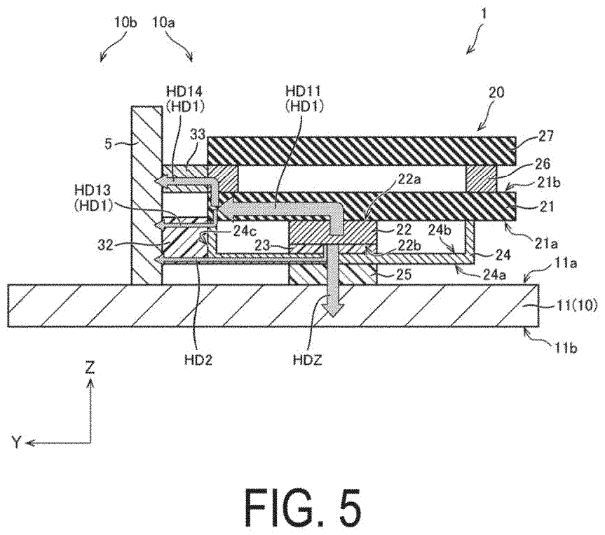

FIG. 5 is a cross-sectional view of an electronic component 1 according to a third modified example of the embodiment. As illustrated in FIG. 5, in the heat source assembly 20 of the electronic component 1 according to the third modified example, a plurality of substrates 21, 27 are layered with an interposer 26 interposed therebetween, and the heat source assembly 20 has a structure further including a third heat transfer component 33 connecting the interposer 26 and the wall portion 5.

The substrate 27 is layered on the substrate 21 so as to face the second surface 21b of the substrate 21 with the interposer 26 interposed therebetween. The substrate 27 is a flat plate made of resin. A circuit and a wiring line are mounted on both main surfaces of the substrate 27.

The interposer 26 is in contact with the second surface 21b of the substrate 21 and a surface of the substrate 27 facing the second surface 21b. The interposer 26 includes a plurality of inter-substrate wiring lines made of a conductor such as copper and an insulating portion made of resin containing the plurality of inter-substrate wiring lines. The interposer 26 electrically connects the substrate 21 and the substrate 27 by connecting the plurality of inter-substrate wiring lines to wiring lines of each of the substrate 21 and the substrate 27. The interposer 26 surrounds a space between the substrate 21 and the substrate 27.

The third heat transfer component 33 connects the interposer 26 and the wall portion 5. The third heat transfer component 33 is provided to form a path HD14 that transfers heat, which has been transferred from the heat source component 22 to the interposer 26 through the substrate 21, from the interposer 26 to the wall portion 5. For example, the third heat transfer component 33 is provided so as to extend along the front surface 11a of the heat receiving component 11. The third heat transfer component 33 can be formed using a thermally conductive material called a TIM, for example. For example, the third heat transfer component 33 can be flexible, sheet-like, grease-like, or gel-like.

The third heat transfer component 33 is provided in this way, so that the heat source component 22 and the wall portion 5 can be indirectly connected via the substrate 21, the interposer 26, and the third heat transfer component 33. This can form the path HD11 and the path HD14 of the first heat release path HD1. The heat transferred to the wall portion 5 is transferred to the heat receiving component 11 over the wall portion 5.

Note that, in the electronic component 1 according to the third modified example as well, the second heat transfer component 32 is provided, and thus the first heat release path HD1 including the path HD11 and the path HD12 is also formed.

In addition, in the electronic component 1 according to the third modified example as well, the second heat release path HD2 is formed. In other words, as the second heat release path HD2, a path is formed in which heat generated by the heat source component 22 is transferred from the heat source component 22 to the case component 24, directed to the wall portion 5 over the case component 24 in the direction along the front surface 11a of the heat receiving component 11 (Y-axis direction), further transferred from the case component 24 to the second heat transfer component 32, transferred over the second heat transfer component 32 in the direction along the front surface 11a of the heat receiving component 11 (Y-axis direction), and transferred from the second heat transfer component 32 to the wall portion 5. The heat transferred to the wall portion 5 is transferred to the heat receiving component 11 over the wall portion 5.

In this manner, the electronic component 1 according to the third modified example includes the interposer 26 provided on the substrate 21 and the third heat transfer component 33. The third heat transfer component 33 connects the interposer 26 and the wall portion 5. The first heat release path HD1 includes the path HD11 passing through the substrate 21, and the path HD14 passing through the interposer 26 and through the third heat transfer component 33 from the substrate 21. This can efficiently transfer heat from the heat source component 22 to the wall portion 5 and transfer the heat from the wall portion 5 to the heat receiving component 11, as compared to a case where the first heat release path HD1 is not formed.

Furthermore, in the space surrounded by the interposer 26, the substrate 21, and the substrate 27, heat cannot be directly transferred to the heat receiving component 11. However, by providing the third heat transfer component 33 that connects the interposer 26 and the wall portion 5, it is possible to efficiently release heat in the space surrounded by the interposer 26, the substrate 21, and the substrate 27, as compared to a case where the third heat transfer component 33 is not provided.

Furthermore, a substrate in which a plurality of layers such as the substrate 21, the interposer 26, and the substrate 27 are layered has a large thickness (width in the Z-axis direction) as the heat source assembly 20, as compared to a single layer substrate. Thus, a thickness (width in the Z-axis direction) of the third heat transfer component 33 connecting the interposer 26 and the wall portion 5 can be made larger than that of a single layer substrate, so that it is possible to efficiently release heat in the space surrounded by the interposer 26, the substrate 21, and the substrate 27.

In addition, a wiring line and the like are provided on the surface of the substrate 27 on the side opposite to the surface facing the substrate 21. Thus, a large area of the third heat transfer component 33 cannot be brought into contact with the surface of the substrate 27 on the side opposite to the surface facing the substrate 21. On the other hand, no wiring line or the like is provided on the side surface outside the interposer 26, so that it is possible to increase the thickness (width in the Z-axis direction) of the third heat transfer component 33 connecting the interposer 26 and the wall portion 5. This can efficiently release heat from the heat source component 22 and also release heat in the space surrounded by the interposer 26, the substrate 21, and the substrate 27.

Note that elements appearing in the embodiment and the modified examples described above may be combined as appropriate within a range in which contradiction does not occur.

While there have been described what are at present considered to be certain embodiments of the invention, it will be understood that various modifications may be made thereto, and it is intended that the appended claim cover all such modifications as fall within the true spirit and scope of the invention.

What is claimed is:

1. An electronic component comprising:
a heat source component provided on a substrate;
a case component covering the heat source component;
a heat receiving component facing the case component; and
a wall portion protruding from the heat receiving component, the wall portion configured to transfer heat indirectly transferred from the heat source component to the heat receiving component,
wherein a heat release path of heat indirectly transferred from the heat source component to the wall portion includes a path away from the heat receiving component, the path extending in a wall portion direction toward the wall portion in a direction along a front surface of the heat receiving component.

2. The electronic component according to claim 1,
wherein the path extending in the wall portion direction includes a first heat release path extending to the wall portion through the substrate.

3. The electronic component according to claim 2, further comprising:
a first heat transfer component connecting the substrate and the wall portion,
wherein the first heat release path includes a path extending from the substrate to the wall portion through the first heat transfer component.

4. The electronic component according to claim 1,
wherein the path extending in the wall portion direction includes a second heat release path extending to the wall portion through the case component.

5. The electronic component according to claim 4, further comprising:
a second heat transfer component connecting the case component and the wall portion,
wherein the second heat release path includes a path extending from the case component to the wall portion through the second heat transfer component.

6. The electronic component according to claim 5,
wherein the second heat transfer component is in contact with the wall portion and a side surface of the case component facing the wall portion.

7. The electronic component according to claim 2, further comprising:
an interposer provided on the substrate; and
a third heat transfer component connecting the interposer and the wall portion,
wherein the first heat release path includes a path extending to the wall portion through the substrate, the interposer, and the third heat transfer component.

8. The electronic component according to claim 1,
wherein the case component and the wall portion are in contact with each other.
